(19) United States
(12) Patent Application Publication
(10) Pub. No.: US 2025/0358963 A1
(43) Pub. Date: Nov. 20, 2025

(54) COLD PLATE WITH HIGH-ASPECT RATIO MICRO- OR NANO-TUBES, AND ASSOCIATED METHODS AND SYSTEMS

(71) Applicant: CoolIT Systems, Inc., Calgary (CA)

(72) Inventors: Anas Mahmoud Atieh, Calgary (CA); Steven Walton, Bell Canyon, CA (US); Seyed Kamaleddin Mostafavi Yazdi, Calgary (CA); Bradley Zakaib, Calgary (CA)

(21) Appl. No.: 19/201,637

(22) Filed: May 7, 2025

Related U.S. Application Data
(60) Provisional application No. 63/644,163, filed on May 8, 2024.

(51) Int. Cl. H05K 7/20

(52) U.S. Cl. CPC H05K 7/20272; H05K 7/20254; H05K 7/20263

(57) ABSTRACT

A cooling system has a cooling loop for cooling one or more heat-generating components. A pump circulates a coolant through the cooling loop. An internally cooled cold plate defines a major surface and a plurality of microtubes extending from an open first end to an opposed open second end. The plurality of microtubes is fluidically coupled with the pump. The internally cooled cold plate is configured to transfer heat received through the major surface to the coolant as the coolant passes through the plurality of microtubes. The plurality of microtubes can provide a ratio of exposed surface area available for heat transfer to volume (SA/V) greater than about 200 m⁻¹. The plurality of microtubes can extend through one or more of an alloy of copper, an alloy of aluminum, and a thermally conductive composite. A heat radiator rejects heat from the coolant to another medium.

### CROSS-REFERENCE TO PERTINENT APPLICATIONS

This application claims benefit of and priority to provisional U.S. Patent Application No. 63/644,163, filed May 8, 2024, the contents of which patent application is hereby incorporated by reference to the same extent as if reproduced in full, for all purposes.

This application and the subject matter disclosed herein (collectively referred to as the “disclosure”) pertain to heat-transfer between a solid and a liquid, and more particularly but not exclusively to principles and techniques described in U.S. Pat. No. 8,746,330, issued Jun. 10, 2014, which claims benefit of and priority from U.S. Provisional Patent Application No. 60/954,987, filed Aug. 9, 2007, the contents of which patent and patent application are hereby incorporated by reference to the same extent as if reproduced in full, for all purposes.

### FIELD

This disclosure generally concerns components that facilitate or provide heat transfer between a solid and a liquid, together with associated systems and methods. More particularly, but not exclusively, this disclosure pertains to liquid- and two-phase cooling systems that facilitate a transfer heat from one or more heat-generating components to a fluid (e.g., in a liquid state, a gaseous state, or a saturated mixture of liquid and gas) passing through a cold plate having a plurality of micro-tubes (sometimes also referred to as nanotubes), together with related methods and systems.

### BACKGROUND INFORMATION

New generations of electronic components, such as, for example, memory components, microprocessors, graphics processors, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks. Some have previously proposed removing heat from a plurality of heat-generating components arranged in close proximity with each other using a single, air-cooled heat sink.

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

### SUMMARY

Presently disclosed cooling devices and systems provide further improved cooling performance compared to previously proposed cooling devices and systems. For example, in contrast to previously proposed techniques, disclosed cold plates provide a heat-exchanger core defining a plurality of microtubes through which a coolant (e.g., a liquid coolant, a gaseous coolant, or a saturated mixture of liquid and gas) can flow, absorbing heat from the walls of the tubes. For example, a liquid- or a refrigerant-cooled cold plate can be placed into thermal contact with a heat-generating component, e.g., the cold plate can have a thermally conductive based placed into thermal contact with the heat-generating component. Heat generated by the component can transfer (e.g., by conduction heat transfer) into the base, which can then conduct into heat-exchanger core among the microtubes. As the coolant (or refrigerant) flows through the plurality of microtubes, the coolant can absorb heat from the solid walls of the microtubes via convection heat transfer. The heated coolant can then carry (advect) the absorbed heat away of the heat-exchanger core. As will be understood by a person of ordinary skill in the art following a review of this disclosure, a thermal interface material can be disposed between any two surfaces described herein as being placed in thermal contact with each other to enhance thermal coupling between those surfaces.

An internally cooled cold plate defines a major surface and a plurality of microtubes extending from an open first end to an opposed open second end. The cold plate is configured to transfer heat received through the major surface to a coolant passing through the plurality of microtubes.

A heat exchanger core can define the plurality of microtubes and a base can define the major surface.

A portion of the base can extend peripherally outward of the heat-exchanger core.

The major surface can be a first major surface positioned opposite the heat-exchanger core and the portion of the base that extends peripherally outward of the heat-exchanger core can define a second major surface positioned opposite the first major surface. The internally cooled cold plate can be further configured to transfer heat received through the second major surface to the coolant passing through the plurality of microtubes.

The plurality of microtubes can be a first plurality of microtubes and the internally cooled cold plate can further define a second plurality of microtubes extending from an open first end to an opposed open second end. The first ends of the first plurality of microtubes and the first ends of the second plurality of microtubes can be spaced apart from each other by a manifold.

The heat exchanger core can define a pair of opposed end walls defining respective open second ends of the first plurality of microtubes and open second ends of the second plurality of microtubes. The manifold can be defined by a recessed groove positioned between the pair of opposed end walls.

The manifold can extend transversely relative to the first plurality of microtubes and the second plurality of microtubes.

In some embodiments, the manifold has a perimeter and the internally cooled cold plate further includes a seal extending around the perimeter of the manifold.

Some internally cooled cold plates include a cover positioned overtop the heat-exchanger core so as to engage with the seal and provide a fluid passage to or from the manifold.

The plurality of microtubes can provide a ratio of exposed surface area available for heat transfer to volume (SA/V) greater than about 200 m⁻¹.

The plurality of microtubes can extend through one or more of an alloy of copper, an alloy of aluminum, and a thermally conductive composite.

The plurality of microtubes can include a plurality of rows of microtubes positioned overtop each other to define a plurality of columns of microtubes.

The plurality of microtubes can include a plurality of rows of microtubes positioned overtop and laterally offset from each other.

The plurality of microtubes can include one or more curved microtubes.

A cooling system has a cooling loop for cooling one or more heat-generating components. The cooling loop includes a pump to circulate a coolant through the cooling loop, as well as an internally cooled cold plate defining a major surface and a plurality of microtubes extending from an open first end to an opposed open second end. The plurality of microtubes are fluidically coupled with the pump. The internally cooled cold plate is configured to transfer heat received through the major surface to the coolant as the coolant passes through the plurality of microtubes. A heat radiator is fluidically coupled with the pump and configured to reject heat from the coolant to another medium as the coolant passes through the heat radiator.

The plurality of microtubes can be a first plurality of microtubes and the internally cooled cold plate can further define a second plurality of microtubes extending from an open first end to an opposed open second end. The first ends of the first plurality of microtubes and the first ends of the second plurality of microtubes can be spaced apart from each other by a manifold.

The heat exchanger core can define a pair of opposed end walls defining respective open second ends of the first plurality of microtubes and open second ends of the second plurality of microtubes. In some embodiments, the manifold is defined by a recessed groove positioned between the pair of opposed end walls.

The manifold can extend transversely relative to the first plurality of microtubes and the second plurality of microtubes.

The plurality of microtubes can provide a ratio of exposed surface area available for heat transfer to volume (SA/V) greater than about 200 m⁻¹.

The plurality of microtubes can extend through one or more of an alloy of copper, an alloy of aluminum, and a thermally conductive composite.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 schematically illustrates a closed liquid-cooling loop.

FIG. 2 illustrates an isometric view of a cold plate with high-aspect ratio microtubes (or nanotubes).

FIG. 3 illustrates a magnified view of a portion of the cold plate shown in FIG. 2 revealing detail of a heat-exchanger core.

FIG. 4 schematically illustrates features of a representative microtube (or nanotube) within the heat-exchanger core shown in FIGS. 2 and 3.

FIG. 5 schematically illustrates features of another representative microtube (or nanotube) within the heat-exchanger core shown in FIGS. 2 and 3.

FIG. 6 is a line drawing showing another isometric view of the cold plate in FIG. 2, together with a magnified view of a portion of an inlet manifold to the heat-exchanger core shown in FIGS. 2 and 3.

FIG. 7 schematically illustrates an embodiment of a bifurcating flow through the cold plate shown in FIGS. 2, 3 and 6.

FIG. 8 schematically illustrates an embodiment of a converging flow through the cold plate shown in FIGS. 2, 3, 6 and 7.

FIG. 9 shows a cross-sectional, isometric view of the cold plate shown in FIGS. 2, 3 and 6.

FIG. 10 shows a side-elevation of the cross-section shown in FIG. 9.

FIG. 11 schematically illustrates an embodiment of microtubes having a longitudinal cross-sectional contour that corresponds to a streamline's contour in a vertical impinging flow over a plate.

FIG. 12 illustrates an isometric views of a hybrid cold plate from above.

FIG. 13 illustrates an isometric view of the hybrid cold plate shown in FIG. 12 from below.

### DETAILED DESCRIPTION

The following describes various principles related to cooling systems, and more particularly but not exclusively to cold plates. Such cooling systems can provide an active closed cooling circuit (or loop) that includes a cold plate to cool one or a plurality of heat-generating components. Moreover, such cold plates can be combined with one or more passive cooling loops to facilitate heat transfer from one or a plurality of nearby heat-generating components to a disclosed cold plate. Such cold plates can also be incorporated in a hybrid cold plate, e.g., as described in U.S. Patent Application Ser. No. 63/558,645, filed Feb. 27, 2024, U.S. Patent Application Ser. No. 63/575,623, filed on Apr. 6, 2024, and U.S. Patent Application Ser. No. 63/633,584, filed on Apr. 12, 2024.

Active closed cooling circuits are described, for example, in U.S. Pat. No. 9,496,200, issued Nov. 15, 2016, and U.S. Pat. No. 9,453,691, issued Sep. 27, 2016, the contents of which patents are hereby incorporated by reference to the same extent as if reproduced herein in full, for all purposes. Active closed cooling circuits also are described in co-pending U.S. patent application Ser. No. 18/297,561, filed on Apr. 7, 2023, now U.S. Pat. No. 12,185,498, issued Dec. 11, 2024. Such closed cooling circuits can incorporate one or more internally cooled cold plates to cool one or more heat-generating components, e.g., as described, for example, in U.S. Pat. No. 8,746,330, issued Jun. 10, 2014, U.S. Pat. No. 11,725,886, issued Aug. 15, 2023, and co-pending U.S. Patent Application Ser. No. 63/533,847, filed Aug. 21, 2023.

Passive two-phase heat-transfer components are described, by way of example, in U.S. Patent Application Ser. No. 63/526,917, filed on Jul. 14, 2023. As the passive, two-phase cold plates thermally couple a plurality of heat-generating components (e.g., DRAMS) with a liquid-cooled condenser block in U.S. Patent Application Ser. No. 63/526,917, disclosed cold plates can incorporate one or more passive heat-transfer components (e.g., a thermally conductive plate or sheet or a vapor chamber, heat pipe, or other passive two-phase heat-transfer component) that thermally couples one or more heat-generating components (e.g., heat-generating power components, chiplets, DRAMs, etc.) with an internally cooled cold plate that is itself thermally coupled with one or more other heat-generating components (e.g., a processing unit, a chipset, a multi-chip module, etc.). Such an arrangement has been disclosed, for example, in co-pending U.S. Patent Application No. 63/558,645, filed Feb. 27, 2024. Disclosed heat-exchanger cores having a plurality of microtubes as described herein can be incorporated in such internally cooled cold plates.

The contents of each patent and patent application identified immediately above and elsewhere in this disclosure are hereby incorporated by reference to the same extent as if each respective patent and patent application was reproduced in full, for all purposes.

Some aspects of disclosed principles pertain to internally cooled cold plates (whether single-phase or two-phase cold plates) suitable for directly cooling one or more heat-generating components (e.g., by being in direct thermal contact with the heat-generating components). (Unless expressly stated otherwise, or unless the context requires a different conclusion, reference herein to an “internally cooled cold plate” refers to single-phase cold plates and two-phase cold plates.) Some aspects of disclosed principles pertain to internally cooled cold plates for indirectly cooling one or more other heat-generating components, e.g., by being indirectly thermally coupled with the one or more other heat-generating components via an intervening passive heat-transfer component. Some aspects of disclosed principles pertain to combining an internally cooled cold plate with one or more passive heat-transfer components to define a hybrid cold plate. Some aspects of disclosed principles pertain to integrating several components with each other to define a hybrid cold plate suitable for meeting cooling demands of a plurality of heat-generating components and for accommodating dimensional variations (e.g., variations in height, which is sometimes referred to in the art as a “tolerance stack up”) across the plurality of heat-generating components, as well as for mounting to a motherboard or other substrate to which the plurality of heat-generating components are mounted.

That said, descriptions herein of specific component and apparatus configurations, and combinations of method acts, are but particular examples drawn on as being convenient, illustrative examples of disclosed principles. One or more of the disclosed principles can be incorporated in various other configurations and systems to achieve any of a variety of desired characteristics corresponding to such other configurations and systems.

Thus, systems having attributes that are different from those specific examples discussed herein can embody one or more presently disclosed principles and can be used in applications not described herein in detail. Accordingly, such alternative embodiments also fall within the scope of this disclosure.

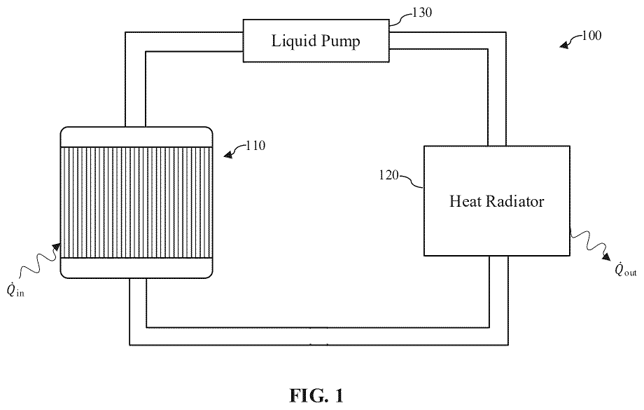

As noted above, FIG. 1 schematically illustrates a closed liquid-cooling loop 100. The liquid-cooling loop 100 includes a heat exchanger 110 that removes heat, \dot{Q}ᵢₙ, from a component (not shown) that generates heat while operating. However, the heat exchanger 110 need not be limited to cooling a single electronic component that dissipates heat while operating. For example, some electronic devices, e.g., servers (alone or installed in a rack, which itself may be installed in a data center), desktop computers, power electronics devices, etc., include a multi-chip module. And, some electronic devices include more than one such multi-chip module. Further, some multi-chip modules require rates of cooling beyond that which air cooling alone can achieve within some electronic devices. Accordingly, some electronic devices require augmented cooling for some or all components mounted to, for example, a multi-chip module.

Accordingly, the heat exchanger 110 shown in FIG. 1 can be configured to cool the heat-generating components of one or more multi-chip modules, or to cool another plurality of heat-generating components, e.g., mounted to a motherboard or other substrate. For example, the heat exchanger 110 can receive heat directly or indirectly from each of a plurality of components and transfer the heat to a coolant passing through the heat exchanger. As described above in connection with FIG. 1, the coolant can flow from the heat exchanger 110 to a heat radiator 120, carrying the received heat to the radiator. As the heated coolant flows through the heat radiator, heat, \dot{Q}ₒᵤₜ, can be transferred to another cooling medium, cooling the coolant. The cooled coolant can again pass through the heat exchanger 110 to remove further heat dissipated by the heat-generating components of the one or more multi-chip modules (and/or other components). Additionally, one or more pumps 130 can urge the coolant throughout the components of the cooling loop 100.

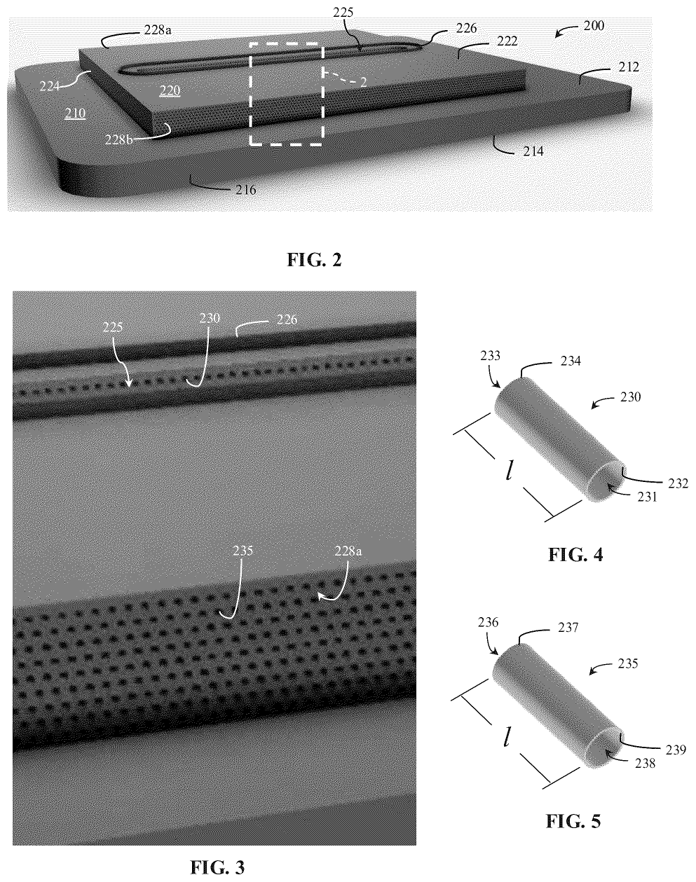

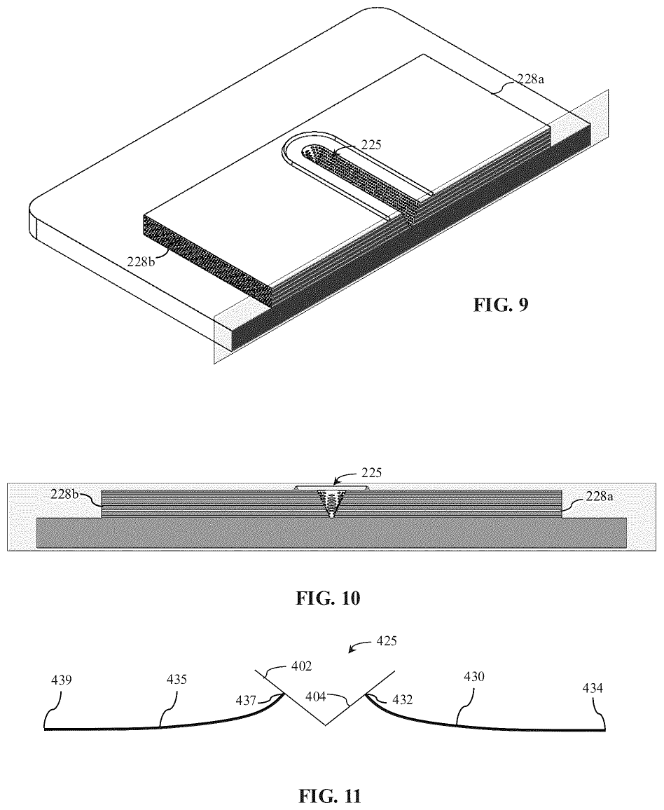

Referring now to FIGS. 2 through 11, principles pertaining to a heat exchanger 110 will be described in context of cold plates that incorporate a heat-exchanger core having a plurality of microtubes, e.g., rather than a plurality of microchannels between fins or a microporous structure as in, for example, U.S. Pat. No. 8,746,330. Bundles of microtubes in disclosed heat-exchanger cores provide a similar function to such microchannels and microporous structure, and solid portions of disclosed heat-exchanger cores provide a similar function to fins or other extended heat-transfer surfaces, insofar as the bundles of microtubes, like microchannels between fins, provide a high ratio of exposed surface area available for heat transfer to volume.

Further, disclosed microtube heat exchanger cores, and the cold plates that incorporate them, can omit previously required housing components while maintaining their function. For example, in U.S. Pat. No. 8,746,330, a top cap or other housing member in an embodiment overlies a base plate defining a plurality of microchannels. The top cap, in combination with the base plate, defines an inlet passage to the microchannels and an outlet passage from the microchannels. As well, the '330 patent describes in connection with an embodiment therein that a plate is positioned overtop the fins. The plate closes off an upper extent of the microchannels, and a seal (which may be installed as a portion of the plate or separately) separates the inlet passage from the outlet passage. Consequently, coolant flows through the microchannels rather than bypasses them.

By contrast to microchannels defined by a gap between adjacent fins, disclosed microtubes are enclosed between discrete openings, e.g., typically located at the microtube's opposed ends. Thus, once coolant enters a microtube, it will not leak from the microtube but instead will flow along the microtube until it reaches a discrete opening, e.g., typically at an end of the microtube positioned longitudinally opposite the end that the coolant entered.

Turning now to FIGS. 2 to 10, an embodiment of a cold plate having a heat-exchanger core defining a plurality of high-aspect ratio microtubes will be described. As FIGS. 2, 3 and 6 show, a cold plate 200 can have a base 210. The depicted base 210 has a top 212 and a lower surface 214 that defines a heat-transfer surface of the cold plate 200. The lower surface 214 can define an intended heat-transfer region to be placed into thermal contact with a heat-generating component (not shown), allowing the base to absorb heat from the heat-generating component. The top surface 212 can likewise define an intended heat-transfer region to be placed into thermal contact with a heat-generating component or into thermal contact with another heat-transfer component (e.g., a heat pipe, a vapor chamber, or simply a thermally conductive solid) that is in thermal contact with a heat-generating component. The illustrated embodiment of the base 210 shows a sidewall 216 having a height corresponding to a thickness of the base 210 between the top 212 and the lower surface 214. Typically, the base 210 can be manufactured from a thermally conductive material, e.g., an alloy of copper, an alloy of aluminum, a thermally conductive composite, and combinations thereof, to facilitate conduction from the lower surface 214 to the heat-exchanger core 220 through which coolant flows.

The illustrated heat exchanger core 220 has an upper surface 222 and a sidewall 224 corresponding to a thickness of the heat exchanger core 220 between the top of the base 212 and the upper surface 222. As described more fully below, the heat-exchanger core 220 defines a plurality of microtubes 230. Each microtube, in the illustrated heat exchanger core, extends laterally across the heat exchanger core 220 between opposed endwalls 228a, 22b from an first open end to an opposed second open end.

In the embodiment shown in FIG. 2, the microtubes are positioned between the top 212 of the base 210 and the upper surface 222 of the heat-exchanger core. The top surface 212 in the illustrated embodiment is a distinctly identifiable feature of the base 210 insofar as the base 210 extends laterally outward of the heat-exchanger core 220. In other embodiments, the sidewall 216 extending around a perimeter of the base 210 is coextensive with the sidewall 224 and the endwalls 228a, b of the of the heat-exchanger core. Thus, the top 212 of the base 210 can be a surface as shown in FIG. 2 or the top 212 of the base 210 can be an internal plane (or other identifiable boundary) between the base 210, e.g., where heat transfer may be dominated by conduction heat transfer, and the heat-exchanger core 220, e.g., where heat transfer may be significantly influenced by convection heat transfer (e.g., heat transferred to the coolant flowing through the bundle of microtubes) as well as conduction heat transfer through the solid portion of the heat-exchanger core.

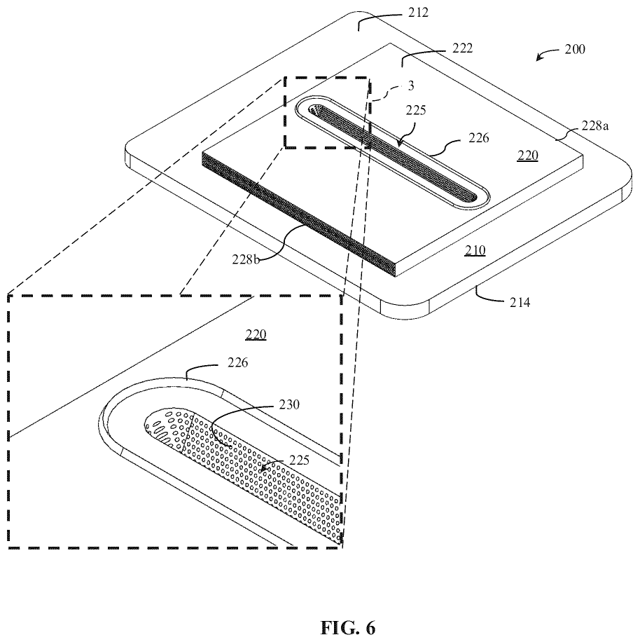

The heat-exchanger core 220 defines a recessed groove extending transverse to the plurality of microtubes 230, 235 forming a manifold 225 in the heat-exchanger core. As the cross-section in FIG. 10 and the enlarged region 3 in FIG. 6 show, the recessed groove may be a V-shaped groove defining a v-shaped cross-section (e.g., as in FIG. 10), though the groove may define other cross-sectional shapes, e.g., a parabolic, round, oval, square or rectangular cross-section. And, although shown as being generally centrally positioned between the end walls 228a, 228b, the manifold 225 can be biased laterally toward one or the other end walls 228a, 228b. Similarly, the manifold 225 is shown as being perpendicular to the microtubes 230, 235, but in other embodiments, the manifold can be transverse to the microtubes in a manner that defines an oblique angle between a longitudinal axis of the manifold and a longitudinal axis of the microtubes. Still further, just one manifold 225 is shown in FIG. 2, but some heat-exchanger cores define a plurality of manifolds extending transversely to the microtubes, providing a one or more inlets to the microtubes or one or more outlets from the microtubes, or one or more of both.

Returning to the heat-exchanger core 220 shown in FIG. 2, two bundles of microtubes are shown. In the first bundle, each microtube 230 extends from a first open end 232 open to or from the manifold 225 to an opposed second open end 234 open to or from a first endwall 228a of the heat-exchanger core 220. In the second bundle, each microtube 236 extends from a first end 237 open to or from the manifold 225 to an opposed second end 239 open to or from a second endwall 228b of the heat-exchanger core 220.

A seal 226, e.g., an o-ring or other gasket, extends around a perimeter of the manifold 225. In some embodiments, the seal 226 is a compressible, pliant member, such as, for example, an o-ring set within a recessed groove (not shown) defined by the upper surface 222 of the heat-exchanger core 220. In other embodiments, the seal 226 is a raised boss, flange or other protrusion having an outer surface to which a diffuser, plate or other member can attach via bonding or fusing so as to provide a fluid-tight connection that prevents or substantially inhibits coolant from moving past the seal 226. In some embodiments, for example, a top cap (not shown) similar to the top cap 244 of U.S. Pat. No. 8,746,330 can be positioned overtop the heat-exchanger core so as to engage with the seal 226 and provide a fluid passage to or from the manifold 225, while also providing a plenum to or from the microtubes 230, 235 positioned laterally outward of the endwalls 228a, 228b. In some embodiments, the downwardly extending sidewalls of the top cap (not shown but, for example, similar to the downwardly extending sidewalls of the top cap 244 in the '330 patent) mate with the base 210 in a manner sufficient to prevent or inhibit leakage of coolant from the plenum. In some embodiments, the downwardly extending sidewalls of the top cap are positioned laterally outward of one or both sidewalls 224 of the heat-exchanger core, as well as laterally outward of the endwalls 228a, b of the heat-exchanger core 220 so as to couple the plenum to or from the first bundle of microtubes (e.g., microtubes 230) with the plenum to or from the second bundle of microtubes (e.g., microtubes 235).

The heat-exchanger core 220 shown in FIG. 2 may predominantly receive heat from the base 210. For example, the heat exchanger core 220 can conductively receive heat from the base 210 and conductively convey the heat through the thickness of the heat-exchanger core from the top 212 of the base to the upper surface 222 of the heat-exchanger core, transferring heat to the coolant passing through the plurality of microtubes 230.

Nevertheless, as with the top 212 and lower surface 214 of the base 210, the upper surface 222 of the heat-exchanger core can define an intended heat-transfer region to be placed into thermal contact with a heat-generating component (not shown) or into thermal contact with a heat-transfer component that is in thermal contact with a heat-generating component. Thus, in some embodiments, the heat-exchanger core 220 shown in FIG. 2 may receive heat from the base 210 as well as from the upper surface 222. In such embodiments, heat can conduct from the upper surface 222 toward the top 212 of the base 210 and from the top 212 of the base toward the upper surface 222, while being absorbed and carried away from the heat-exchange core by the coolant passing through the heat-exchanger core 220.

In some embodiments, disclosed microtubes provide a substantially higher ratio of exposed surface area available for heat transfer to volume (SA/V) than a microchannel cold plate using a skiving technique. For example, a microchannel cold plate using a skiving technique to produce the fins (and thus the microchannels therebetween, referred to herein as “skived microchannels”) can typically provide SA/V of between about 200 m⁻¹ and about 300 m⁻¹. By comparison, disclosed heat exchanger cores can provide between about 10 and about 100 microtubes, e.g., between 30 and about 60 microtubes, or between about 40 and about 50 microtubes, to provide comparable surface area within the same volume occupied by two skived fins and the skived microchannel therebetween. However, such a heat exchanger core provides substantially more solid, conductive material (e.g., about twice as much solid, conductive material). By providing additional conductive material in the heat exchanger core with comparable surface area, conductive spreading resistance through the heat exchanger core is reduced. By reducing the spreading resistance through the heat-exchanger core, surfaces of microtubes exposed to coolant passing through the microtubes at positions distal from the heat source will have higher temperature, and thus an increased rate of convective heat transfer. Stated differently, an effective measure of “fin efficiency” or other measure of conductive heat transfer through the heat exchanger core will increase, improving performance of the heat exchanger core compared to prior skived heat exchanger cores within an equivalent volume.

Thus, by providing substantially higher mass per SA/V, disclosed heat exchanger cores can provide higher overall rates of heat transfer to a coolant passing through the cold plate, substantially increasing the overall cooling capacity of the microtube cold plate compared to a microchannel cold plate. The increase in mass provided by disclosed microtubes can be attained by densely packing microtubes together into one or more microtube bundles.

As used herein, the term “microtube” refers to a longitudinally extending bore having a mean hydraulic diameter of between about 100 μm to about 1.5 mm. Disclosed microtubes can range in length (e.g., longitudinal distance from one open end to an opposed open end) from about 5 mm to about 250 mm. Such microtubes can be formed within a billet of material using, for example, any of a variety of techniques such as, for example, laser ablation, micro-EDM drilling, micro-drilling and micro-machining. As but one particular example, micro-EDM machines capable of forming microtubes as described herein in aluminum and copper are commercially available from SARIX SA of Switzerland.

A disclosed heat-exchanger core can provide one or more bundles (or arrays) of microtubes extending through, e.g., an otherwise solid material, e.g., a thermally conductive alloy of copper or aluminum, or a thermally conductive composite. In some embodiments, a bundle of microtubes stacks a plurality of rows of microtubes overtop each other with columns of microtubes spaced apart from each other according to a pitch along each row. For example, a row of microtubes can space walls of microtubes apart from each other by one hydraulic diameter. Such a row of microtubes, therefore, can have a lateral pitch equal to twice the hydraulic diameter of the microtubes. Similarly, each row of microtubes can have a vertical pitch equal to twice the hydraulic diameter. In some heat-exchanger core embodiments, each vertical row of microtubes is laterally shifted by, for example, one hydraulic diameter, relative to the rows of microtubes immediately above and below the respective row. Such a lateral offset can provide a vertical pitch less than one hydraulic diameter while maintaining, for example, at least one hydraulic diameter wall thickness between adjacent pairs of microtubes. This can be desirable to maintain acceptable vertical conduction heat transfer through the heat-exchanger core, as conductive heat transfer will wane vertically (assuming a single heat source applied to the base 210 of the cold plate), similar to the rate of conductive heat transfer through an extended heat-transfer surface, or fin. And, at some point, additional rows of microtubes will yield ever diminishing marginal increases in heat transfer, e.g., due to a phenomenon analogous to that which reduces fin efficiency of convectively cooled heat-transfer surfaces extending from a heated base.

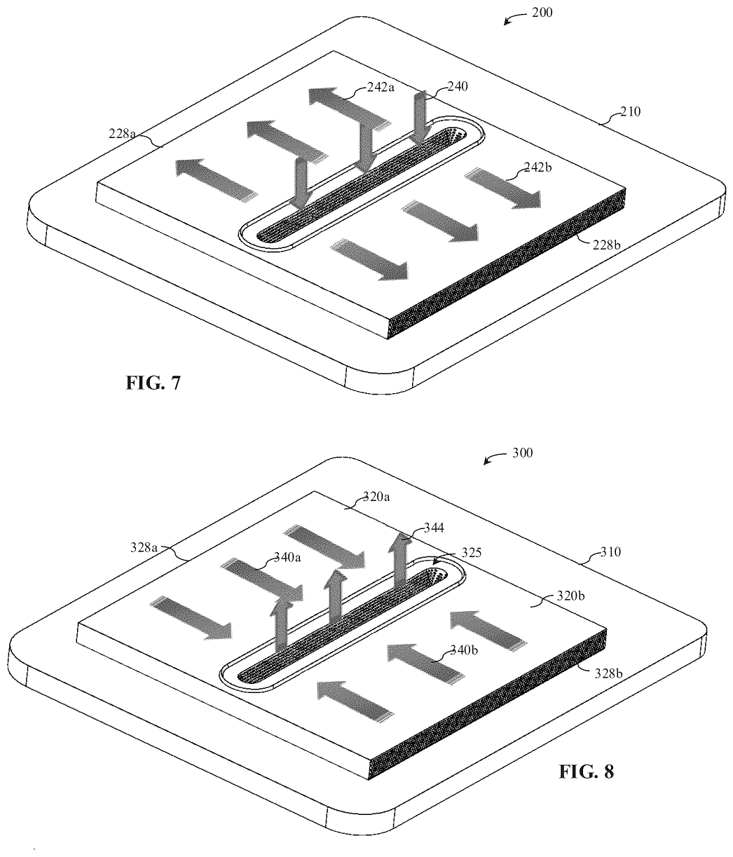

The cold plate 200 may be operated in a split-flow configuration (FIG. 7) or in a convergent flow configuration (FIG. 8). For example, as depicted in FIG. 7, cool coolant can enter the manifold 225, as depicted by the downwardly directed arrows 240. As the coolant enters the manifold 225, the coolant can bifurcate into outwardly directed subflows (depicted by arrows 242a, b). More particularly, one of the subflows 242a can flow from the manifold 225 into the microtube inlets 231, along the microtubes 230 and out from the microtube outlets 233 opening from the endwall 228a. Similarly, the other of the subflows 242b can flow from the manifold 225 into the microtube inlets 236, along the microtubes 235 and out from the microtube outlets 237 opening from the endwall 228b.

Conversely, as depicted in FIG. 8, converging first and second inlet flows 340a, 340b of coolant can enter the first and the second microtube bundles 320a, 320b from the respective opposed endwalls 328a, 328b. As the converging first and second inlet flows 340a, 340b pass through the microtube bundles 320a, 320b, the coolant absorbs heat conducted to the heat exchanger core from the base 310 (or from the upper surface of the heat-exchanger core, or from both). The converging flows 340a, 340b exhaust from the microtubes and combine in the outlet manifold 325, depicted by the upwardly directed arrows 344.

In the foregoing embodiments, the microtubes are described as extending longitudinally. Although such microtubes maybe “straight,” e.g., a longitudinal axis of the microtube may be a straight segment of a line, microtubes need not be straight. Indeed, in some embodiments, a curved microtube may be desirable. In such curved microtube embodiments, a longitudinal axis of the microtube may be curved. Nevertheless, such a curved microtube may be described as extending longitudinally and it will be understood that such longitudinal extension should be construed as being relative to the curved longitudinal axis of the microtube. For example, referring now to FIG. 11, a pair of opposed, curved microtubes 430, 435 are shown extending laterally outward from the manifold 425 and having a longitudinal curvature corresponding to opposed streamlines arising from an impinging flow on a flat plate. In the embodiment shown, the inlets 432, 437 are perpendicular to the walls 404, 402, respectively, defining the recessed, V-shaped groove and the outlets 434, 439 are perpendicular to the endwalls (not shown) of the heat-exchanger core. In other embodiments, the inlets 432, 437 are transverse but not necessarily perpendicular to the walls 402, 404. Similarly, in some embodiments, the outlets 434, 439 are transverse but not necessarily perpendicular to the endwalls.

Thermal interface materials described herein can include thermal greases, thermal gap pads, thermal gels, thermal interface foils, etc. To facilitate variability in vertical height, e.g., from aggregated manufacturing tolerances, some thermal interface materials will desirably be able to compress to a greater degree than other thermal interfaces.

Referring again to the schematic illustration in FIG. 1, a cold plate incorporating a heat-exchanger core as just described can be substituted for the heat exchanger 110. For example, the cold plate 200 shown in FIG. 2 may be placed in thermal contact with a processing component. On reviewing this disclosure, a person of ordinary skill in the art will understand and appreciate the various modifications to fluid connections, pumping resources, and radiator configurations that such alternative arrangements could or would require in order to urge a sufficient flow of coolant through each heat exchanger/heat-exchanger assembly in a given cooling loop, as well as to reject absorbed heat from the coolant to another cooling medium.

Such cooling systems also can include a heat radiator configured to reject heat from the coolant to another medium as the coolant passes through the heat radiator, generally as described above in connection with FIG. 1. Such cooling systems also include a pump configured to urge the coolant throughout a closed loop.

As noted above, a heat-exchanger core with high-aspect ratio microtubes disclosed herein can also be incorporated in a hybrid cold plate. For example, in contrast to previously proposed techniques that provide a large, single-mode heat sink (or cold plate) placed in thermal contact with a plurality of closely arranged heat-generating components, disclosed hybrid cold plates combine, for example, a liquid- or a refrigerant-cooled cold plate (e.g., an internally cooled cold plate with a heat-exchanger core having high-aspect ratio microtubes) with a passive heat-transfer component. Such a hybrid cold plate can have a significantly lower mass compared to a large, single-mode heat sink while effectively cooling a plurality of closely arranged heat-generating components.

Some disclosed hybrid cold plates provide a liquid- or a refrigerant-cooled heat-exchanger core having a plurality of microtubes for (1) directly cooling one or more, e.g., high-power, low-temperature (or both), heat-generating components; and (2) indirectly cooling one or more other, e.g., relatively-lower power, higher-temperature (or both), heat-generating components. For example, such a hybrid cold plate can provide a passive heat-transfer component to transfer heat from the one or more indirectly cooled heat-generating components to the liquid- or a refrigerant-cooled cold plate with microtubes. By way of further example, the passive heat-transfer component can conductively receive heat from each of the one or more heat-generating components indirectly cooled by the liquid- or a refrigerant-cooled cold plate. The passive heat-transfer component can also convey such received heat and transfer it to the liquid- or refrigerant cooled cold plate with microtubes, which in turn facilitates a transfer of such heat to a coolant (or a refrigerant) passing through the cold plate.

In some embodiments, the passive heat-transfer component includes a thermally conductive solid that conveys heat from the one or more heat-generating components to the liquid- or refrigerant-cooled cold plate. For example, such a thermally conductive solid can span across one or more components and facilitate heat transfer from the one or more components to a liquid-cooling loop (or a two-phase cooling loop). By way of further example, the thermally conductive solid can conduct heat from the one or more heat-generating components to an internally cooled cold plate, which in turn can facilitate a transfer of the heat to a single- or a two-phase coolant passing through the cold plate.

In some embodiments, the passive heat-transfer component includes a passive, two-phase cold plate that conveys heat from the one or more heat-generating components to the liquid- or refrigerant-cooled cold plate spans. For example, such a passive, two-phase cold plate can span across one or more components and facilitate heat transfer from the one or more components to a liquid-cooling loop (or a two-phase cooling loop). By way of further example, the a passive, two-phase cold plate can convey heat from the one or more heat-generating components to an internally cooled cold plate, which in turn can facilitate a transfer of the heat to a single- or a two-phase coolant passing through the heat-exchanger core.

As but one illustrative example, one or more passive, two-phase cold plates, e.g., vapor-chamber cold plates, heat-pipe cold plates, etc., can thermally couple with (e.g., conductively) one or more heat-generating components positioned near, for example, a processing unit. Similarly, a cold plate fluidly coupled with a single-phase or a two-phase cooling loop can be thermally coupled with (e.g., a conductively coupled with) the processing unit, and heat generated by the processing unit can be transferred to the coolant circulating through the cooling loop. Further, the one or more passive, two-phase cold plates can be thermally coupled with (e.g., conductively) the cold plate fluidly coupled with the single-phase or two-phase cooling loop, enhancing cooling of the one or more heat-generating components by transferring heat from those components to the cold plate, and thereby to a coolant flowing through the cooling loop.

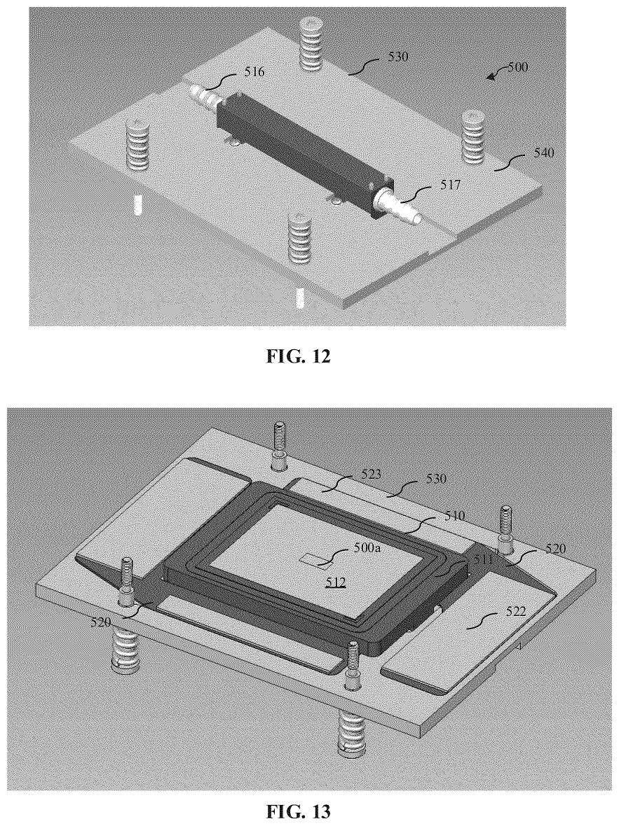

An internally cooled cold plate disclosed herein can be mounted or mountable with a packaged semiconductor. The internally cooled cold plate can have an inlet 516 (FIG. 12) and an outlet 517. Although such an inlet and an outlet are not depicted in FIGS. 2 to 11, those of ordinary skill in the art will appreciate that internally cooled cold plates as described in connection with FIGS. 2 to 11 will provide an inlet to and an outlet from the heat exchanger core having microtubes.

Some packaged semiconductors incorporate a lid or IHS positioned overtop the active (e.g., heat-generating) die, while other packaged semiconductors omit such a lid or IHS. Some packaged semiconductors incorporate a plurality of dice (sometimes referred to in the art as “chiplets”) and a lid or an IHS overlies one or more (or all) of the chiplets. In other embodiments, no lid or IHS overlies any of the chiplets.

FIG. 12 shows a hybrid cold plate 500 having an internally cooled cold plate 510 (FIG. 13) with a heat exchanger core having microtubes as described above, together with a pair of passive heat-transfer components 520. Each of the internally cooled cold plate 510 and the pair of passive heat-transfer components 520 is configured to be placed into thermal contact (e.g., with or without an intervening thermal interface material) with one or more corresponding heat-generating components, such as, for example, voltage regulation components, DRAMs or communication bridges, or other chipsets.

The internally cooled cold plate 510 defines a base region 511. The base region 511 can be placed in thermal contact with a corresponding region of a heat-generating component (e.g., represented by the heat source 500a) to conductively receive heat generated by the heat-generating component. A thermal interface material 512 can be disposed between the base region 511 of the internally cooled cold plate 510 and the heat-generating component to facilitate conductive heat transfer across the interface between the internally cooled cold plate 510 and the heat-generating component. The heat-generating component can have a lid or an IHS overlying an active component and the thermal interface material 512 can be disposed between the base region 511 of the internally cooled cold plate 510 and the lid or IHS. In other embodiments, no lid or IHS overlies an active component and the thermal interface material 512 can be disposed between the base region 511 of the internally cooled cold plate 510 and the active component (or a backside of the die thereof).

Similarly, the passive heat-transfer components 520 define respective base regions 521. Each respective base region 521 can be placed in thermal contact with a corresponding region of one or more heat-generating components to conductively receive heat generated by the one or more heat-generating components. A thermal interface material 522, 523 can be disposed between the base region 521 of the passive heat-transfer components 520 and the respective one or more heat-generating components to facilitate conductive heat transfer across the interface between the passive heat-transfer components 520 and the one or more heat-generating components.

The internally cooled cold plate 510 also defines a top region (analogous to top 212 in FIG. 2). The top region of the internally cooled cold plate can be placed in thermal contact with a corresponding portion of the base region 521 of one or both of the passive heat-transfer components 520. Such thermal contact between the internally cooled cold plate 510 and one or both of the passive heat-transfer components 520 can transfer heat conveyed by the passive heat-transfer component from the one or more heat-generating components to the internally cooled cold plate, and thus to the coolant passing through the microtubes of the heat exchanger core thereof. As with other thermal interfaces described herein, a thermal interface material can be disposed between the base region 521 of one or both of the passive heat-transfer components 520 and the top region of the internally cooled cold plate 510 to facilitate conductive heat transfer across the interface between the passive heat-transfer component 520 and the internally cooled cold plate 510. In some embodiments, one or more of the passive heat-transfer components 520 is a vapor chamber device having one or more condensing regions positioned adjacent the top region of the internally cooled cold plate 510 and one or more evaporating regions positioned adjacent one or more of the heat generating components. In some embodiments, one or more of the passive heat-transfer components 520 is a heat pipe having a condensing region positioned adjacent the top region and an evaporating region spanning across one or more of the heat generating components. In some embodiments, one or more of the passive heat-transfer components 520 is a plate or other member made of one or more thermally conductive materials, e.g., an alloy of copper or aluminum.

In some embodiments, the lid or IHS of a packaged semiconductor physically incorporates an internal heat-transfer chamber that receives a liquid coolant or a refrigerant. In such embodiments, the lid or IHS of the packaged semiconductor includes an internally cooled cold plate. In such embodiments, for example, a semiconductor device manufacturer can produce the packaged semiconductor and mount the internally cooled cold plate to the die, similar in some respects to how semiconductor device manufacturers currently attach the lid or IHS to the die. However, unlike known lids and IHS embodiments that rely on conduction heat transfer to spread heat through the lid or IHS, some embodiments can incorporate a disclosed heat exchanger core having microtubes in a device package, e.g., the heat exchanger core can be configured as a lid or IHS.

A cooling system as just described can be installed in or on an electronic device to cool a single heat-generating component or a multi-chip module alone, or in combination with other heat-generating components (e.g., processing units). And, a typical memory module, for example, may have between four and forty, or more, active electronic components (e.g., DRAMs), as well as additional heat-dissipating components like power delivery devices, memory controllers, EEPROMs, etc. Moreover, a given electronic device may have an array of multi-chip modules installed, with each module being cooled by a cooling system as described above. For example, such an array of multi-chip modules may include one or more multi-chip modules, or one or more pairs of multi-chip modules.

Nonetheless, the previous description is provided to enable a person skilled in the art to make or use embodiments of the disclosed principles. Embodiments other than those described above in detail are contemplated based on the principles disclosed herein, together with any attendant changes in configurations of the respective apparatus or changes in order of method acts described herein, without departing from the spirit or scope of this disclosure. For example, the manifolds shown in the drawings are defined by forming a recessed groove. Nevertheless, EDM drilling and other subtractive manufacturing techniques can define complexly shaped internal passageways within a material. Such techniques, therefore, can be adapted to define a manifold that extends internally within the heat-exchanger core, transverse to one or more bundles of microtubes. Such an arrangement, for example, can eliminate a plate or top cap, as well as a seal, overlying the illustrated manifolds. Similarly, with such subtractive manufacturing techniques, the endwalls 228a, 228b, together with each plenum that delivers coolant to or receives coolant from the microtube openings in the endwalls 228a, 228b, can be formed internally of the heat-exchanger core 220, further eliminating seams or interfaces between, e.g., a top cap and the base 210, that can leak coolant, while still providing the benefits of the manifolds and plenums. Accordingly, a disclosed heat-exchanger core can eliminate all mechanical connections except, for example, an inlet coupler for delivering coolant to the heat-exchanger core and an outlet coupler for exhausting heated coolant from the heat-exchanger core. Various other modifications to the embodiments described herein will be readily apparent to those skilled in the art.

For example, concepts described herein can be used to cool a plurality of other types of heat-generating components that are combined into a functional module (e.g., as with a DIMM or another multichip module, e.g., a processing unit that includes one or more processing cores or chips, together with one or more voltage regulating components (so-called “VR components”) or other modules that include, for example, a so-called intermediate bus converter (IBC).

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface, and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling devices for multi-chip modules, and related methods and systems to remove waste heat from such multi-chip modules. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling devices, and related methods and systems that can be devised using the various concepts described herein.

Moreover, nothing disclosed herein is intended to be dedicated to the public regardless of whether such disclosure is explicitly recited in the claims. No claim feature is to be construed under the provisions of 35 USC 112 (f), unless the feature is expressly recited using the phrase “means for” or “step for”.

Reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the following claims, as well as the combinations recited, literally and equivalently, in any claims presented anytime throughout prosecution of this application or any application claiming benefit of or priority from this application.

1. An internally cooled cold plate defining a major surface and a plurality of microtubes extending from an open first end to an opposed open second end, the cold plate being configured to transfer heat received through the major surface to a coolant passing through the plurality of microtubes.

2. The internally cooled cold plate according to claim 1, comprising a
a heat-exchanger core defining the plurality of microtubes; and
a base defining the major surface.

3. The internally cooled cold plate according to claim 2, wherein a portion of the base extends peripherally outward of the heat-exchanger core.

4. The internally cooled cold plate according to claim 3, wherein the major surface is a first major surface positioned opposite the heat-exchanger core and wherein the portion of the base that extends peripherally outward of the heat-exchanger core defines a second major surface positioned opposite the first major surface, wherein the internally cooled cold plate is further configured to transfer heat received through the second major surface to the coolant passing through the plurality of microtubes.

5. The internally cooled cold plate according to claim 1, wherein the plurality of microtubes is a first plurality of microtubes and wherein the internally cooled cold plate further defines a second plurality of microtubes extending from an open first end to an opposed open second end, wherein the first ends of the first plurality of microtubes and the first ends of the second plurality of microtubes are spaced apart from each other by a manifold.

6. The internally cooled cold plate according to claim 5, wherein the heat exchanger core defines a pair of opposed end walls defining respective open second ends of the first plurality of microtubes and open second ends of the second plurality of microtubes, wherein the manifold is defined by a recessed groove positioned between the pair of opposed end walls.

7. The internally cooled cold plate according to claim 5, wherein the manifold extends transversely relative to the first plurality of microtubes and the second plurality of microtubes.

8. The internally cooled cold plate according to claim 5, wherein the manifold has a perimeter, the internally cooled cold plate further comprising a seal extending around the perimeter of the manifold.

9. The internally cooled cold plate according to claim 8, further comprising a cover positioned overtop the heat-exchanger core so as to engage with the seal and provide a fluid passage to or from the manifold.

10. The internally cooled cold plate according to claim 1, wherein the plurality of microtubes provides a ratio of exposed surface area available for heat transfer to volume (SA/V) greater than about 200 m⁻¹.

11. The internally cooled cold plate according to claim 1, wherein the plurality of microtubes extend through one or more of an alloy of copper, an alloy of aluminum, and a thermally conductive composite.

12. The internally cooled cold plate according to claim 1, wherein the plurality of microtubes comprises a plurality of rows of microtubes positioned overtop each other to define a plurality of columns of microtubes.

13. The internally cooled cold plate according to claim 1, wherein the plurality of microtubes comprises a plurality of rows of microtubes positioned overtop and laterally offset from each other.

14. The internally cooled cold plate according to claim 1, wherein the plurality of microtubes comprises one or more curved microtubes.

15. A cooling system having a cooling loop for cooling one or more heat-generating components, the cooling loop comprising:
a pump to circulate a coolant through the cooling loop;
an internally cooled cold plate defining a major surface and a plurality of microtubes extending from an open first end to an opposed open second end, the plurality of microtubes being fluidically coupled with the pump, the internally cooled cold plate being configured to transfer heat received through the major surface to the coolant as the coolant passes through the plurality of microtubes; and
a heat radiator fluidically coupled with the pump and configured to reject heat from the coolant to another medium as the coolant passes through the heat radiator.

16. The cooling system according to claim 15, wherein the plurality of microtubes is a first plurality of microtubes and wherein the internally cooled cold plate further defines a second plurality of microtubes extending from an open first end to an opposed open second end, wherein the first ends of the first plurality of microtubes and the first ends of the second plurality of microtubes are spaced apart from each other by a manifold.

17. The cooling system according to claim 16, wherein the heat exchanger core defines a pair of opposed end walls defining respective open second ends of the first plurality of microtubes and open second ends of the second plurality of microtubes, wherein the manifold is defined by a recessed groove positioned between the pair of opposed end walls.

18. The cooling system according to claim 16, wherein the manifold extends transversely relative to the first plurality of microtubes and the second plurality of microtubes.

19. The cooling system according to claim 15, wherein the plurality of microtubes provides a ratio of exposed surface area available for heat transfer to volume (SA/V) greater than about 200 m⁻¹.

20. The cooling system according to claim 15, wherein the plurality of microtubes extend through one or more of an alloy of copper, an alloy of aluminum, and a thermally conductive composite.
